(19) United States
(12) Patent Application Publication
(10) Pub. No.: US 2015/0303179 A1
(43) Pub. Date: Oct. 22, 2015

(54) Light Emitting Diode Assembly With Integrated Circuit Element

(71) Applicant: Toshiba Corporation, Tokyo (JP)

(72) Inventors: Kai Liu, Pleasanton, CA (US); Chao-Kun Lin, San Jose, CA (US)

(73) Assignee: TOSHIBA CORPORATION, Tokyo (JP)

(21) Appl. No.: 14/256,767

(22) Filed: Apr. 18, 2014

(51) Int. Cl. H01L 25/16; H01L 33/62; H01L 33/48; H01L 33/36; H01L 23/528; H01L 21/768; H01L 29/866; H01L 29/66

(52) U.S. Cl. CPC H01L 25/167; H01L 29/866; H01L 33/62; H01L 29/66106; H01L 33/36; H01L 23/528; H01L 21/768; H01L 25/165; H01L 33/486; H01L 2933/0016; H01L 2933/0066

(57) ABSTRACT

An LED assembly with an ESD protection device integrated into the carrier substrate and a method for making the LED assembly is disclosed. In one embodiment, the LED assembly includes an LED in contact with a bonding layer in contact with a substrate. The substrate has a region containing a circuit element. The bonding layer forms an ohmic connection between the region containing the circuit element and the LED. In one embodiment, the region containing the circuit element is an ESD protection device, such as a Zener diode.

### FIELD OF THE INVENTION

The invention relates generally to a light emitting diode (LED) assembly, and particularly to an LED assembly with an ESD protection device integrated into the carrier substrate.

### BACKGROUND

Traditional light emitting diode (LED) chips begin with a semiconductor growth substrate, generally a group III-V compound such as gallium arsenide (GaAs), gallium phosphide (GaP), indium phosphide (InP), and gallium arsenide phosphide (GaAsP). The semiconductor growth substrate may also be sapphire (Al₂0₃), silicon (Si), and silicon carbide (SiC) for group III-Nitride based LEDs. Epitaxial semiconductor layers are grown on the semiconductor growth substrate to form the N-type and P-type semiconductor layers of the LED. The epitaxial semiconductor layers may be formed by a number of developed processes including, for example, Liquid Phase Epitaxy (LPE), Molecular-Beam Epitaxy (MBE), and Metal Organic Chemical Vapor Deposition (MOCVD). After the epitaxial semiconductor layers are formed, electrodes are added to the N-type and P-type semiconductor layers using known photolithography, etching, evaporation, and polishing processes. Individual LED chips are diced and mounted to a package with wire bonding. An encapsulant is deposited onto the LED chip and the LED chip is sealed with a protective lens which also aids in light dispersion.

One major drawback to the traditional LED chip is that many types of semiconductor growth substrate, such as silicon (Si), will absorb the photons that are emitted downward from the LED to the semiconductor growth substrate, reducing the overall light extraction efficiency of the LED chip. Even if the semiconductor growth substrate does not absorb visible light, such as sapphire (Al₂0₃) or silicon carbide (SiC), the photons emitted downward will still be absorbed by the package, also reducing the overall light extraction efficiency of the LED chip. Other drawbacks of the traditional LED chip include poor heat dissipation due to the high internal resistance of the semiconductor growth substrate and poor current spreading due to the lateral flow of current through the LED. To overcome these issues, a vertical LED (VLED) chip was developed.

FIGS. 1A-G show the manufacturing steps for creating a conventional VLED chip. In FIGS. 1A and 1B, an epitaxial growth process forms an N-type epitaxial semiconductor layer 101 on a semiconductor growth substrate 100, such as sapphire (Al₂0₃). In FIG. 1C, an epitaxial growth process forms a P-type epitaxial semiconductor layer 102 on top of the N-type epitaxial semiconductor layer 101. In FIG. 1D, a metal bonding layer 103 is deposited on top of the P-type epitaxial semiconductor layer 102. The metal bonding layer 103 is a conductive material, for example gold tin (AuSn) or silicon gold (SiAu), and may comprise multiple conductive layers made of different types of conductive materials, including a mirror layer (not pictured). The mirror layer generally comprises a material having a high degree of reflectivity, for example aluminum (Al), silver (Ag), or Rhodium (Rh).

In FIG. 1E, a conventional wafer bonding process, such as eutectic bonding where heat and pressure are used to form an ohmic connection, bonds a first surface 104a of a carrier substrate 104 to the metal bonding layer 103. The carrier substrate 104 generally comprises a material with high thermal conductivity and high electro-conductivity, such as single crystal materials such as silicon, sapphire, or silicon carbide, or ceramic materials, such as aluminum nitride, silica, or metallic materials having good heat conductivity such as aluminum, copper, nickel, or alloys thereof. In FIG. 1F, the semiconductor growth substrate 100 has been removed. Removal of the semiconductor growth substrate 100 may be accomplished by any known method, including Laser Lift Off (LLO), mechanical grinding, chemical etching, or any combination thereof. In FIG. 1G, a deposition and etching process forms an N-electrode 105 and a P-electrode 106 on opposite sides of the VLED chip. The N-electrode 105 is formed on the N-type epitaxial semiconductor layer 101 and the P-electrode 106 is formed on a second surface 104b of carrier substrate 104.

The VLED chip allows for greater light extraction efficiency than the traditional LED chip because the photons that are emitted downward from the LED to the carrier substrate are reflected back upwards by the mirror layer, allowing them to escape rather than being absorbed. Other benefits of the VLED chip include improved heat dissipation and current spreading due to the use of a carrier substrate with high thermal conductivity and the vertical current flow through the LED, respectively.

It is well known that electronic components can be easily destroyed by a voltage surge or electrostatic discharge (ESD). LEDs, especially gallium nitride (GaN) based LEDs, are susceptible to destruction when a reverse bias voltage is applied across its anode and cathode. Early solutions contemplated incorporating a discrete ESD protection diode to the same package as the LED chip using wire bonding to connect the discrete ESD protection diode to the LED chip in an anti-parallel configuration as shown in FIG. 2A. During normal operation, a forward bias voltage is applied across terminals A and B and the LED turns on, conducting all of the current through the LED. When a reverse bias voltage is applied across terminals A and B, the discrete ESD protection diode turns on and conducts current away from the LED, preventing the LED from being destroyed.

There are a number of disadvantages to incorporating a discrete ESD protection diode into the LED package, including increased bulk due to the addition of the discrete ESD protection diode to the LED package, reduced light extraction efficiency because the discrete ESD protection diode will block or absorb some of the light emitted from the LED chip, and increased manufacturing cost due to the additional manufacturing steps required to form the wire bonds to connect the discrete ESD protection diode to the LED chip. To address some of these disadvantages, LED chips with an ESD protection diode formed on the substrate were developed.

An example of an LED chip with an ESD protection diode grown on the semiconductor growth substrate is shown in FIG. 2B, which is described in U.S. Pat. No. 6,547,249. In FIG. 2B, an epitaxial growth process forms an N-type epitaxial semiconductor layer and a P-type epitaxial semiconductor layer on a semiconductor growth substrate 201. Using photolithography and etching, a trench bisecting the N-type and P-type epitaxial semiconductor layers is formed, resulting in N-type layers 202a and 202b and P-type layers 203a and 203b. N-type layer 202a and P-type layer 203a comprise an LED and N-type layer 202b and P-type layer 203b comprise an ESD protection diode.

To connect the LED and the ESD protection diode, a dielectric layer 204 is first deposited over the devices to electrically isolate the exposed regions of the N-type layers 202a and 202b and P-type layers 203a and 203b. Using photolithography and etching, an N-contact region and a P-contact region is exposed in the dielectric layer 204 and conductive material is deposited into the exposed regions to form an N-electrode 205 and a P-electrode 206. Finally, metal interconnect 207 connects the N-electrode 205 and the P-electrode 206, connecting the LED and the ESD protection diode in an anti-parallel configuration at the wafer-level.

While the LED chip shown in FIG. 2B realizes cost savings benefits by eliminating the need to attach a discrete ESD diode to the LED chip at the packaging stage of manufacturing, there remains a number of disadvantages to this configuration as well. The ESD protection diode of the LED chip shown in FIG. 2B is created by using part of the N-type and P-type semiconductor layer that form the LED, resulting in a smaller LED area (mesa) and necessarily reducing the overall light output from the LED chip. Additionally, there is added manufacturing cost due to the extra steps needed to form the ESD protection device on the semiconductor growth substrate 201, such as creating the trench and metal interconnect 207.

Further, the light extraction efficiency of the LED package is significantly reduced by either the use of an absorptive semiconductor growth substrate 201, which, as previously mentioned, will absorb the photons that are emitted downward from the LED to the semiconductor growth substrate 201, or a transparent semiconductor growth substrate 201 whereby the package will absorb the photons that are emitted downward from the LED to the package. The light extraction efficiency is further reduced by the metal interconnect 207 and the ESD protection diode blocking or absorbing some of the emitted photons as well. Overall, the LED chip shown in FIG. 2B will only have a small fraction (less than 10%) of the light output and light extraction efficiency of a similarly sized VLED chip without an ESD protection diode.

An alternative to growing the ESD protection diode on the semiconductor growth substrate is to integrate the ESD protection diode into the semiconductor growth substrate. An example of an LED chip with an ESD protection diode integrated into the semiconductor growth substrate is shown in FIG. 2C, which is the preferred embodiment described in U.S. Pat. No. 7,897,497. In FIG. 2C, a P-type dopant is uniformly doped throughout a semiconductor growth substrate 210 having a first surface 210a and a second surface 210b. An N-type dopant is diffused into the first surface 210a of semiconductor growth substrate 201 to create an N-type substrate region 217. A P-type dopant is uniformly diffused over the entire first surface 210a of the growth substrate 210, to a depth less than that of the N-type substrate region 217 to create a P-type substrate layer 211. The junction formed by N-type substrate region 217 and the P-type substrate layer 211 comprises an ESD protection diode integrated into the semiconductor growth substrate 210.

An epitaxial growth process forms an N-type epitaxial semiconductor layer and a P-type epitaxial semiconductor layer on top of the first surface 210a of semiconductor growth substrate 210. Using photolithography and etching, a trench bisecting the N-type and P-type epitaxial semiconductor layers and exposing the P-type substrate layer 211 directly above the N-type substrate region 217 is created, resulting in the formation of N-type layers 212a and 212b and P-type layers 213a and 213b. N-type layer 212a and P-type layer 213a comprise a first LED and N-type layer 212b and P-type layer 213b comprise a second LED.

Buffer layers 214a and 214b for electrical isolation are formed over the exposed regions created by the trench, leaving a contact surface of the P-type substrate layer 211 directly above N-type substrate region 217 exposed. Deposition, lithography and etching processes form top electrodes 215 and 216 on top of P-type layers 213a and 213b, respectively. A back electrode 216 is formed on the second surface 210b of the growth substrate 210. Metal interconnect 215 connects electrodes 216, 217 and the exposed portion of the P-type substrate layer 211, connecting the first LED and the second LED in an anti-parallel configuration with the ESD protection diode.

By integrating the ESD protection diode into the semiconductor growth substrate 210, the LED chip shown in FIG. 2C frees up space on the first surface 210a of the semiconductor growth substrate 210 for additional LED area, resulting in greater overall light output compared to the LED chip shown in FIG. 2B. However, substantial LED area is still sacrificed by creating the trench to expose the contact surface of the ESD protection diode. Additionally, creating the trench, the buffer layers 214a and 214b, and the metal interconnect 215 all require additional manufacturing steps increasing manufacturing time and cost. Further, each of the semiconductor growth substrate 210, the buffer layers 214a and 214b, and the metal interconnect 215 absorb or block photons, greatly reducing the light output efficiency of the LED chip shown in FIG. 2C.

Another example of an LED chip with an ESD protection diode integrated into the substrate is shown in FIG. 2D, which is described in U.S. Pat. No. 8,237,192. In FIG. 2D, a carrier substrate 220 having a first surface 220a and a second surface 220b is partially doped with an N-type dopant to form an N-region 224, and a P-type dopant to form P-type region 223. The N-type region 224 and the P-type region 225 comprise an ESD protection diode integrated into the carrier substrate 220. A barrier layer 225 is formed in the carrier substrate 220 by first etching a trench in the carrier substrate 210. The trench is formed by the use of deep reactive ion etching to form a shallow trench, followed by the application of a passivation layer to prevent the further erosion of the sidewalls of the shallow trench, and using deep reactive ion etching to deepen the trench. The trench is subsequently filled with an insulating material to electrically isolate the ESD protection diode from the remainder of the carrier substrate 220.

A metal bonding layer 227 is deposited over the first surface 220a of the carrier substrate 220. Using photolithography and etching, the portion of the metal layer 227 covering the P-type region 223 is removed, exposing P-type region 223. An LED comprising a P-type layer 221 and an N-type layer 222 is attached to the metal bonding layer 227, with the P-type layer 221 in contact with the metal bonding layer 227. Electrodes 229 and 228 are formed on the first surface 220a and the second surface 220b and the carrier substrate 220. Metal interconnect 230 electrically connects the electrode 229 and the P-type region 223, connecting the LED and the ESD protection diode in an anti-parallel configuration. Insulation layer 231 is deposited around metal interconnect 230, electrically isolating metal interconnect 230 from the metal bonding layer 227, the P-type layer 221, and the N-type layer 222.

The LED chip shown in FIG. 2D is an improvement over the LED chip shown in FIG. 2C because substantial LED area is not sacrificed to create a trench for the interconnection of the LED and the ESD protection diode as required by the LED chip in FIG. 2C. Moreover, the LED chip in FIG. 2D utilizes a VLED structure rather than a traditional LED structure like the LED chip in FIG. 2C, resulting in improved light extraction efficiency, among others. However, further improvements can be made to the device in FIG. 2D because the metal interconnect 230 and the insulation layer 231 absorbs or blocks some of the photons emitted from the LED, reducing the light output efficiency of the overall LED chip. Additionally, formation of the P-type region 223, the N-type region 224, and the barrier layer 225 in the carrier substrate requires numerous additional manufacturing steps, making the device in FIG. 2D costly and time-consuming to produce.

### SUMMARY

In one embodiment, a light emitting diode (LED) assembly includes a substrate comprising a region forming a circuit element. An intervening layer is formed on a surface of the substrate and an LED is formed on the intervening layer. The intervening layer forms an ohmic connection between the region containing the circuit element and the LED. In one embodiment, the intervening layer is a bonding layer, bonding the LED to the substrate.

In one embodiment, the LED and the substrate are connected to a first polarity of a voltage source, and the intervening layer is connected to a second polarity of the voltage source. In another embodiment, a first electrode is electrically coupled to the LED. A second electrode is electrically coupled to the intervening layer. And a third electrode is electrically coupled to the substrate. The first electrode and the third electrode are connected to a first polarity of a voltage source, and the second electrode is connected to a second polarity of the voltage source.

In another embodiment, a passivation layer is formed in between the intervening layer in the substrate, and a interconnect is formed in the passivation layer, the interconnect forming an ohmic connection between the intervening layer and the region containing the circuit element. In one embodiment the circuit element is an electro-static discharge (“ESD”) protection device. In one embodiment, the ESD protection device is a P-N junction. In one embodiment, the ESD protection device is a diode. In one embodiment, the ESD protection device is a Zener diode.

In one embodiment, a method for forming an LED assembly includes providing a substrate comprising a region forming a circuit element. The method further includes forming an intervening layer on a surface of the substrate and forming an LED on the intervening layer. The intervening layer forms an ohmic connection between the region and the LED.

In one embodiment, connecting the LED and the substrate to a first polarity of a voltage source, and connecting the intervening layer to a second polarity of a voltage source. In another embodiment, forming a first electrode electrically coupled to the LED. The embodiment further includes forming a second electrode electrically coupled to the intervening layer. The embodiment further includes forming a third electrode electrically coupled to the substrate. The embodiment further includes connecting the first electrode and the third electrode to a first polarity of a voltage source, and connecting the second electrode to a second polarity of the voltage source.

### BRIEF DESCRIPTION OF THE DRAWINGS

FIGS. 1A-G show a cross-sectional view of manufacturing steps for creating a conventional VLED chip.

FIG. 2A is a schematic electrical diagram of an LED with an ESD protection diode connected in an anti-parallel configuration.

FIG. 2B shows a cross-sectional view of an LED chip with an ESD protection diode grown on the semiconductor growth substrate.

FIG. 2C shows a cross-sectional view of an LED chip with an ESD protection diode integrated into the semiconductor growth substrate.

FIG. 2D shows a cross-sectional view of another LED chip with an ESD protection diode integrated into the substrate.

FIGS. 3A-C shows a cross-sectional view of the manufacturing steps for producing an LED assembly with a circuit element integrated in the carrier substrate, according to one embodiment of the invention.

FIGS. 4A-D shows a cross-sectional view of the manufacturing steps for producing an LED assembly with a circuit element integrated in the carrier substrate, according to another embodiment of the invention.

FIGS. 5A-E shows a cross-sectional view of the manufacturing steps for producing an LED assembly with a circuit element integrated in the carrier substrate, according to another embodiment of the invention.

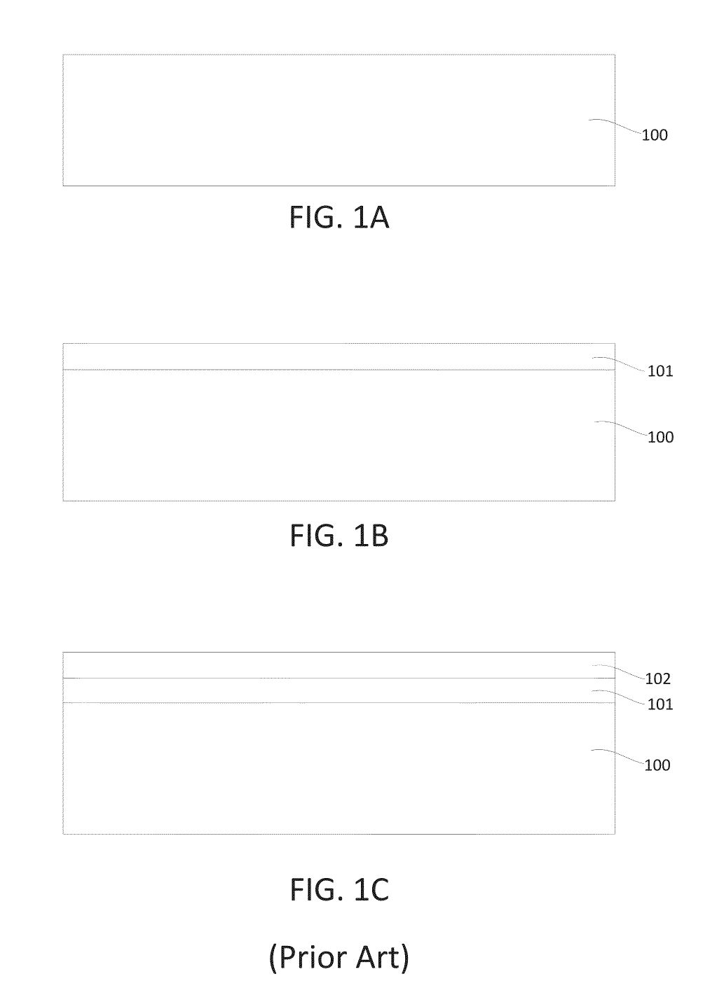

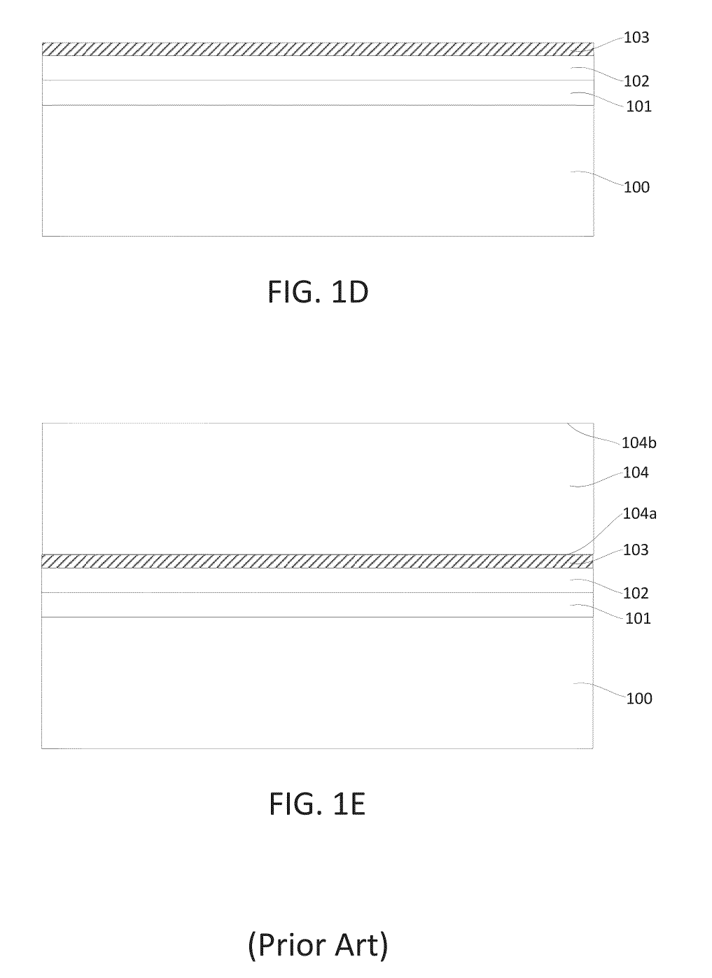

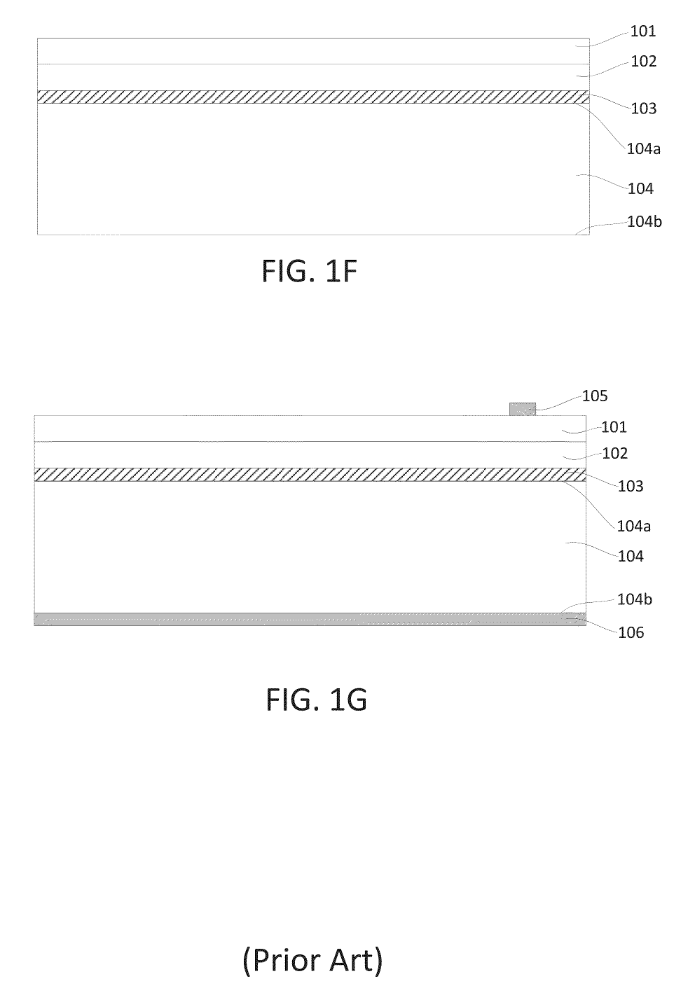

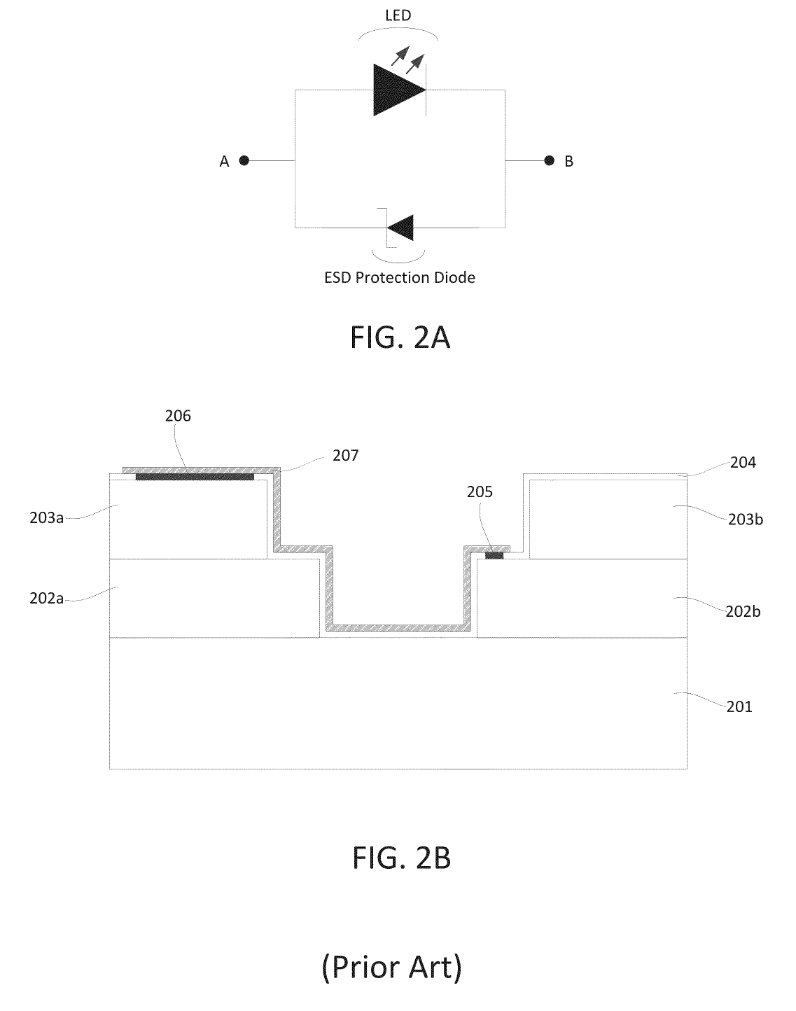

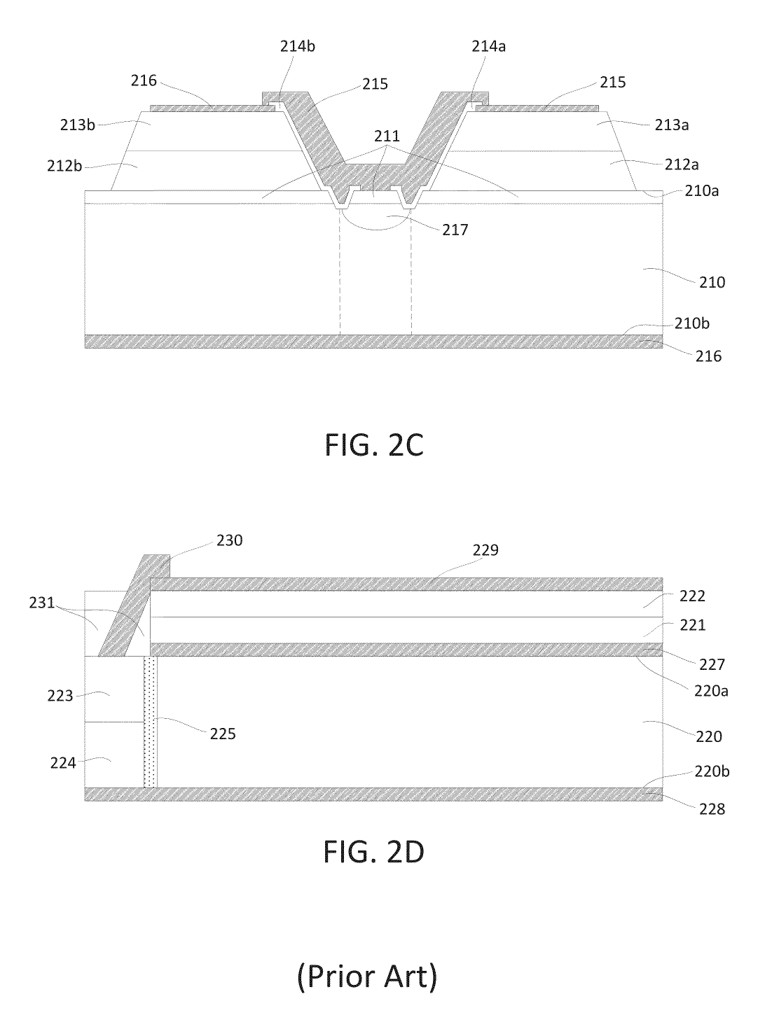

### DETAILED DESCRIPTION

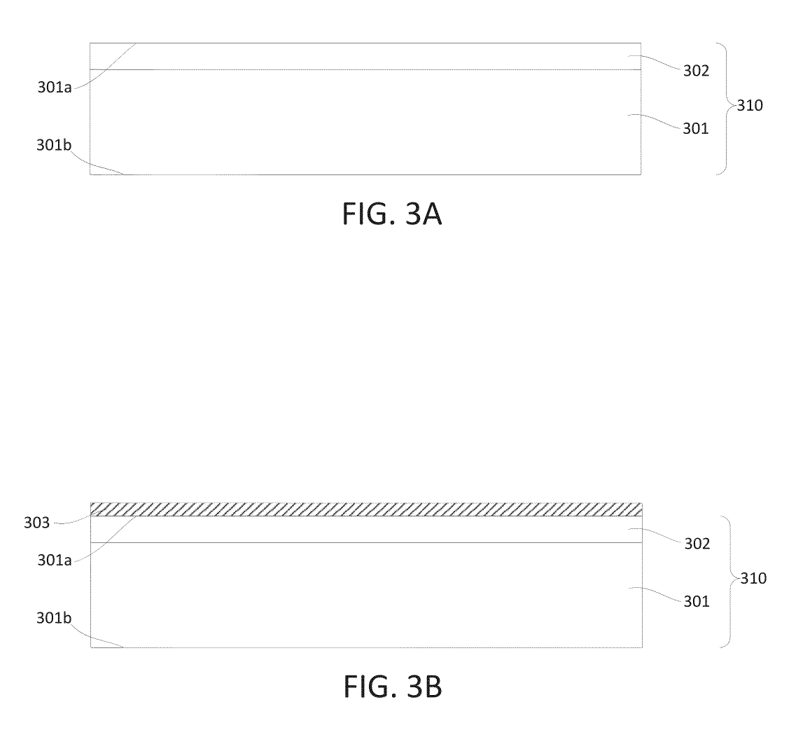

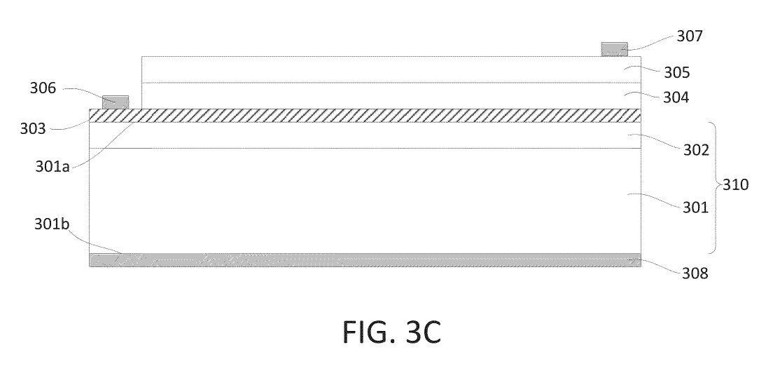

FIGS. 3A-C show cross-sectional views of the manufacturing steps for producing an LED assembly with a circuit element integrated in the carrier substrate, according to one embodiment of the invention. In FIG. 3A, a carrier substrate 301 having a first surface 301a and a second surface 301b is initially of a P-type. In one embodiment, the carrier substrate 301 includes semiconductor materials such as silicon (Si), silicon carbide (SiC), gallium arsenide (GaAs), or germanium (Ge).

An N-type dopant is uniformly diffused into the first surface 301a of the carrier substrate 301 to form an N-type region 302. The carrier substrate 301 and the N-type region 302 comprise a circuit element 310 integrated into the carrier substrate 301. In one embodiment, the circuit element 310 is an ESD protection device. In one embodiment, the circuit element 310 is a P-N junction. In another embodiment, the circuit element 310 is a diode. In another embodiment, the circuit element 310 is a Zener diode. In FIG. 3B, an intervening layer 303 is uniformly deposited onto the first surface 301a of the carrier substrate 301, covering the N-type region 302. In one embodiment, the intervening layer 303 is a bonding layer. In one embodiment, the intervening layer 303 may comprise multiple conductive layers made of different types of conductive materials.

In FIG. 3C, an LED comprising a P-type epitaxial semiconductor layer 304 and an N-type epitaxial semiconductor layer 305 that was formed on a semiconductor growth substrate (not pictured) is bonded to intervening layer 303. The LED is bonded to the intervening layer 303 with the P-type epitaxial semiconductor layer 304 of the LED in contact with the intervening layer 303. In another embodiment, a mirror layer (not pictured) comprising a material having a high degree of reflectivity, such as aluminum (Al), silver (Ag), or Rhodium (Rh) is first deposited on top of the P-type epitaxial semiconductor layer 304 of the LED before the LED is bonded to the intervening layer 303. The intervening layer 303 thus forms an ohmic connection between the P-type epitaxial semiconductor layer 304 of the LED and the N-type region 302 of the carrier substrate 301. In another embodiment, the intervening layer 303 is first uniformly deposited on the surface of the P-type epitaxial semiconductor layer 304 of the LED and the first surface 301a of the carrier substrate is subsequently bonded to the intervening layer 303.

The semiconductor layers forming the LED can be of any known type. In one embodiment, the LED is gallium nitride (GaN) based. In another embodiment, the LED is a group III-phosphide semiconductor compound. In a further embodiment, the LED is a group III-nitride semiconductor compound. The LED has a footprint area that is at least about 50% of the surface area of the carrier substrate 301. In one embodiment, the footprint area of the LED covers 95% or more of the surface area of the carrier substrate 301. The LED is offset from the carrier substrate 301 such that a portion of the intervening layer 303 remains exposed.

Using known deposition, photolithography, and etching techniques, electrodes 306, 307, and 308 for electrical contact are formed on the intervening layer 303, the LED, and the second surface 302b of carrier substrate 301, respectively. The electrode 306 is electrically coupled to the exposed region of the intervening layer 303, the electrode 307 is electrically coupled to the N-type epitaxial semiconductor layer 305 of the LED, and the electrode 308 is electrically coupled to the second surface 301b of carrier substrate 301.

The electrode 306 is the positive terminal of the LED assembly and the electrodes 307 and 308 constitute the negative terminal of the LED assembly, thereby connecting the LED and the circuit element 310 integrated into the carrier substrate 301 in an anti-parallel configuration. When a reverse bias voltage is applied across the positive and negative terminals of the LED assembly, the circuit element 310 will turn on and bypass the current from the LED, preventing the LED from being destroyed.

The light output and light extraction efficiency of the LED assembly with a circuit element 310 integrated in the carrier substrate produced by the manufacturing steps shown in FIGS. 3A-3C is substantially similar to that of a similarly sized VLED chip without an discrete ESD protection diode. Additionally, the LED assembly with a circuit element 310 shown in FIG. 3C requires only one additional manufacturing step as compared to a VLED chip without an ESD protection diode—that is uniformly diffusing an N-type, or in the alternative embodiment a P-type, dopant the first surface 301a of carrier substrate 301 to form the Zener diode integrated into the carrier substrate 301. Thus, the LED assembly with a Zener diode shown in FIG. 3C can be manufactured for a substantially similar cost and in a substantially similar amount of time as a VLED chip without an ESD protection diode.

In one embodiment, the LED assembly of FIGS. 3A-3C may be created using a wafer level packaging process. The basic principle of wafer level packaging is to package a plurality of devices at the same time by packaging an entire wafer before dicing the wafer into individual dies. In full wafer level packaging of LED devices, instead of individual LED dies being bonded to a carrier substrate wafer, a complete device wafer including a plurality of vertical LED devices is bonded to a carrier substrate wafer such that the LED devices are “sandwiched” between the growth substrate of the device wafer and the carrier substrate wafer. The carrier substrate wafer may include conductor and/or dielectric patterns such as pads, trenches, and vias, through vias filled or partially filled with conductive material, scribe lines, alignment marks, and other features such as the circuit element 310. A eutectic metal bonding process may bond the carrier substrate wafer to the top surface of the LED device wafer. A LLO or chemical etching process removes the growth substrate from the “sandwich,” leaving the “flipped” un-diced LED devices bonded to the carrier substrate wafer. A phosphor coating may be deposited over the LED devices on the wafer by dispensing or spraying a phosphor-containing material onto the surface of the wafer.

A compression molding process may then be used to form a lens over each of the LED devices. The wafer is placed in a mold that includes the reverse of a desired lens shape for each lens to be formed on the wafer. The wafer may include alignment marks to ensure that the mold cavities are placed accurately over each of the LED devices. A transparent silicone material preform is placed into the mold and heat is applied to melt the silicon material into the desired shape to form the lenses. In another embodiment, an injection molding process may be used where a transparent silicone material is injected into a mold placed over the carrier substrate wafer. A curing process applied to the lens mold then cures the silicone material to set the lenses and adhere them to the wafer. The curing process may include applying ultraviolet (UV) radiation, thermal radiation (infrared), microwave radiation, or other radiation that can cure the transparent silicone material. The wafer is then carefully removed from the mold so as not to cause the lenses to separate from the wafer. The wafer may now be diced into individual LED packages that each include an LED device on a carrier substrate and a lens covering the LED device.

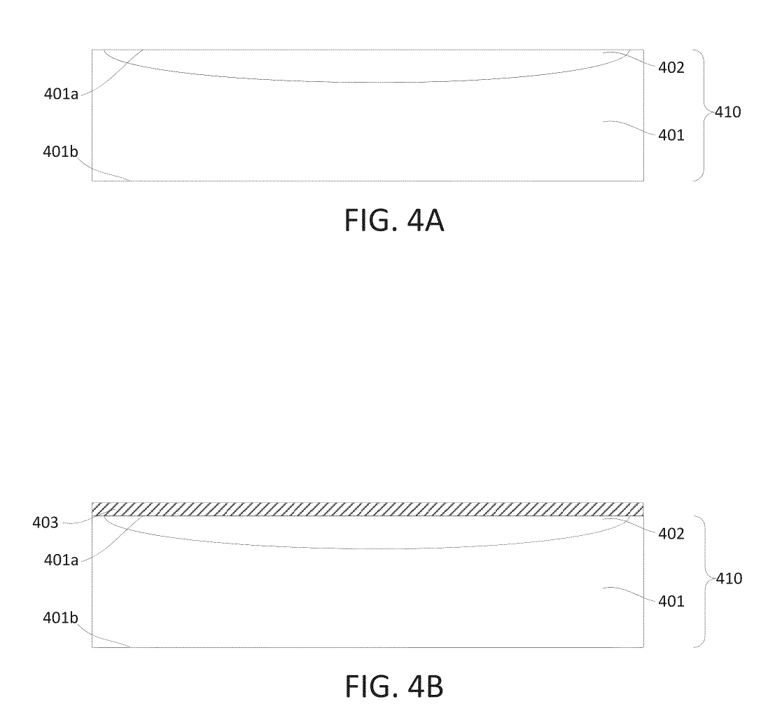

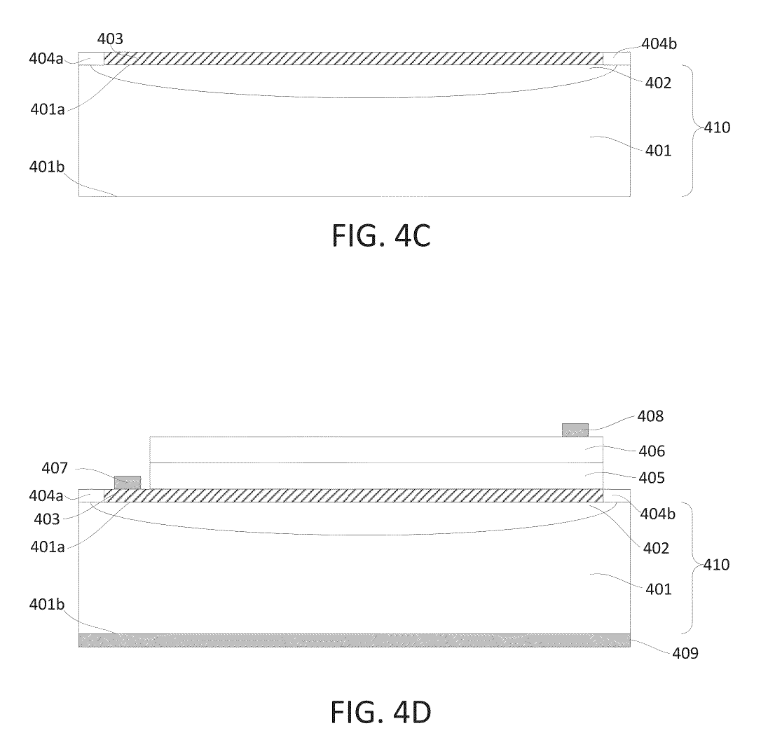

FIGS. 4A-D show cross-sectional views of the manufacturing steps for producing an LED assembly with a circuit element integrated in the carrier substrate, according to another embodiment of the invention. In FIG. 4A, a carrier substrate 401 having a first surface 401a and a second surface 401b is initially of a P-type. In one embodiment, the carrier substrate 401 includes semiconductor materials such as silicon (Si), silicon carbide (SiC), gallium arsenide (GaAs), or germanium (Ge).

An N-type dopant is diffused into the first surface 401a of the carrier substrate 401 to form an N-type region 402. The N-type region 402 is defined by photolithography. The carrier substrate 401 and the N-type region 402 comprise a circuit element 410 integrated into the carrier substrate 401. In one embodiment, the circuit element 410 is an ESD protection device. In one embodiment, the circuit element 410 is a P-N junction. In another embodiment, the circuit element 410 is a diode. In another embodiment, the circuit element 410 is a Zener diode. In FIG. 4B, an intervening layer 403 is uniformly deposited onto the first surface 401a of the carrier substrate 401, covering N-type region 402. In one embodiment, the intervening layer 403 is a bonding layer. In one embodiment, the intervening layer 403 may comprise multiple conductive layers made of different types of conductive materials.

In FIG. 4C, the edges of the intervening layer 403 are etched, exposing passivation regions 404a and 404b. Passivation regions 404a and 404b are subsequently filled with an insulating material for protection and electrical isolation of the exposed passivation regions 404a and 404b.

In FIG. 4D, an LED comprising a P-type type epitaxial semiconductor layer 405 and an N-type epitaxial semiconductor layer 406 is bonded to intervening layer 403 in a similar manner as described in FIG. 3C above, with the intervening layer 403 forming an ohmic connection between the P-type epitaxial semiconductor layer 405 of the LED and the N-type region 402 of the carrier substrate 401.

The LED has a footprint that is that is smaller than the N-type region 402. The LED is offset from the carrier substrate 401 such that a portion of the intervening layer 403 remains exposed, and no part of the LED is in contact with passivation regions 404a and 404b.

Electrode 407 is electrically coupled to the exposed region of the intervening layer 403, electrode 408 is electrically coupled to the N-type epitaxial semiconductor layer 406 of the LED, and electrode 409 is electrically coupled to the second surface 401b of carrier substrate 401. The electrode 407 is the positive terminal of the LED assembly and the electrodes 408 and 409 constitute the negative terminal of the LED assembly, thereby connecting the LED and the circuit element 410 integrated into the carrier substrate 401 in an anti-parallel configuration. In one embodiment, the LED assembly of FIGS. 4A-4D may be created using a wafer-level packaging process as previously described.

The LED assembly with a circuit element integrated in the carrier substrate produced by the manufacturing steps shown in FIGS. 4A-4D has a light output and light extraction efficiency that is substantially similar to the LED assembly produced by the manufacturing steps described in FIGS. 3A-3C. In addition, the LED assembly of FIG. 4D will have reduced current leakage compared with the LED assembly of FIG. 3C, because the circuit element of the LED assembly in FIG. 3C is exposed at the sidewalls after dicing. However, extra manufacturing steps are necessary to form the passivation regions 404a and 404b for the LED assembly of FIG. 4D.

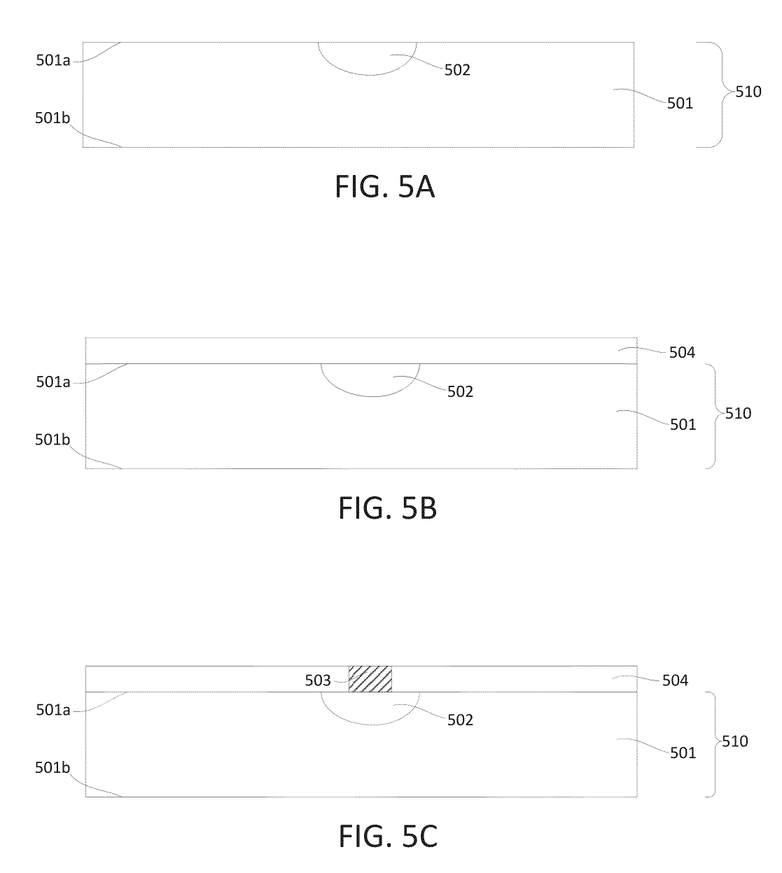

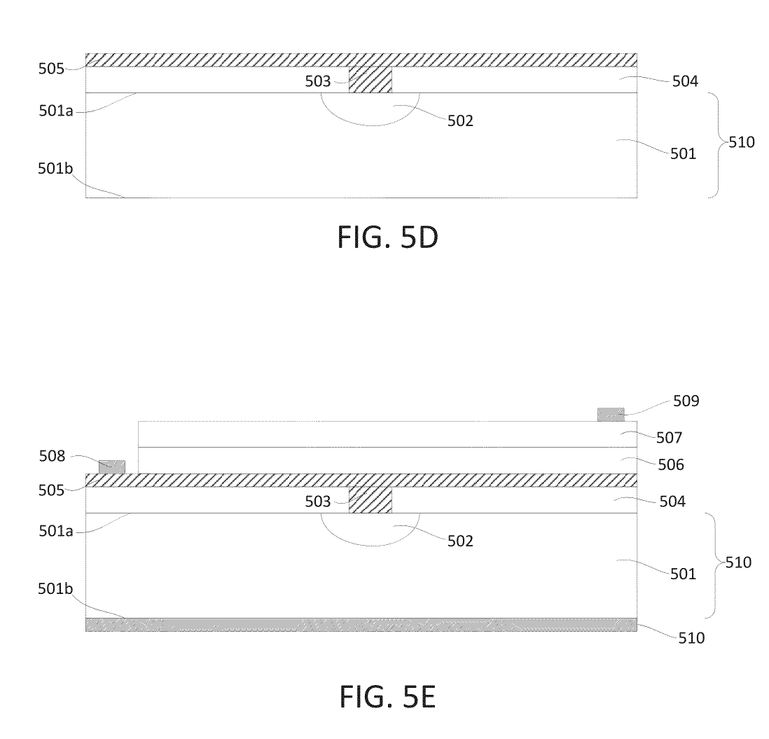

FIGS. 5A-E show cross-sectional views of the manufacturing steps for producing an LED assembly with a circuit element integrated in the carrier substrate, according to another embodiment of the invention. In FIG. 5A, a carrier substrate 501 having a first surface 501a and a second surface 501b is initially of a P-type. In one embodiment, the carrier substrate 301 includes semiconductor materials such as silicon (Si), silicon carbide (SiC), gallium arsenide (GaAs), or germanium (Ge).

An N-type dopant is diffused into the first surface 501a of the carrier substrate 501 to form an N-type region 502. The N-type region 502 is defined by photolithography. The carrier substrate 501 and the N-type region 502 comprise a circuit element 510 integrated into the carrier substrate 501. In one embodiment, the circuit element 510 is an ESD protection device. In another embodiment, the circuit element 510 is a P-N junction. In another embodiment, the circuit element 510 is a diode. In another embodiment, the circuit element 510 is a Zener diode. In FIG. 5B, a passivation layer 504 is uniformly deposited onto the first surface 501a of the carrier substrate 501, covering N-type region 502. The passivation layer 504 is comprises an insulating material for protection and electrical isolation.

In FIG. 5C, photolithography and etching processes form a window region 503 in the passivation layer 504, directly above N-type region 502. The window region 503 is smaller than the N-type region 502, such that no part of the carrier substrate 501 is exposed by the window region 503. Window region 503 is subsequently filled with a conductive material to form an interconnect, the interconnect forming an ohmic connection with N-type region 502. In FIG. 5D, an intervening layer 505 is uniformly deposited on top of the passivation layer 504 and the window region 503. In one embodiment, the intervening layer 505 is a bonding layer. In another embodiment, the intervening layer 505 may comprise multiple conductive layers made of different types of conductive materials.

In FIG. 5E, an LED comprising a P-type type epitaxial semiconductor layer 506 and an N-type epitaxial semiconductor layer 507 is bonded to intervening layer 505 in a similar manner as described in FIGS. 3C and 4D above, with the intervening layer 505 forming an ohmic connection between the P-type epitaxial semiconductor layer 507 of the LED and the N-type region 502 of the carrier substrate 501.

The LED has a footprint area that is that is at least about 50% of the surface area of the carrier substrate 501. In one embodiment, the footprint area of the LED covers 95% or more of the surface area of the carrier substrate 501. The LED is offset from the carrier substrate 501 such that a portion of the intervening layer 505 remains exposed. An electrode 508 is electrically coupled to the exposed region of the intervening layer 505, an electrode 509 is electrically coupled to the N-type epitaxial semiconductor layer 507 of the LED, and an electrode 510 is electrically coupled to the second surface 501b of carrier substrate 501.

The electrode 508 is the positive terminal of the LED assembly and the electrodes 509 and 510 constitute the negative terminal of the LED assembly, thereby connecting the LED and the circuit element 510 integrated into the carrier substrate 501 in an anti-parallel configuration. In one embodiment, the LED assembly of FIGS. 5A-5E may be created using a wafer-level packaging process as previously described.

Again, the light output and light extraction efficiency of the LED assembly with a circuit element integrated in the carrier substrate produced by the manufacturing steps shown in FIGS. 5A-5E is substantially similar to the LED assemblies produced by the manufacturing steps described in FIGS. 3A-3C and FIGS. 4A-4D. Additionally, by reducing the size of the circuit element 510, the reverse leakage current is further reduced at the elevated temperatures LEDs typically operate. The circuit element 510 of the LED assembly in FIG. 5E can also be placed anywhere under the LED, allowing for the circuit element 510 to be placed in an area which has a relatively lower temperature, such as under the electrode 509. The circuit element 510 can also be placed to the periphery of the carrier substrate 501 to allow additional space in the carrier substrate 501 for additional circuit elements to be formed.

The LED assembly in FIG. 5E will require an additional number of manufacturing steps required to form, and the bonding process must be aligned such that the circuit element is properly situated below the LED. The smaller the circuit element, the more accurate the bonding process must be. The LED assembly in FIG. 5E is thus more susceptible to manufacturing defects due to misalignment during the bonding process.

In an alternative embodiment to each of the manufacturing steps as described in FIGS. 3A-C, 4A-D, and 5A-E, the carrier substrate is initially of an N-type, and a P-type dopant is uniformly diffused into the first surface of the carrier substrate to form a P-type region. An LED comprising an N-type epitaxial semiconductor layer and a P-type epitaxial semiconductor layer, is bonded to the intervening layer with the N-type epitaxial semiconductor layer of the LED in contact with the intervening layer.

The intervening layer thus forms an ohmic connection between the N-type epitaxial semiconductor layer of the LED and the P-type region of the carrier substrate. In the alternative embodiment, the electrode electrically coupled to the intervening layer is the negative terminal of the LED assembly and the electrodes electrically coupled to the P-type epitaxial semiconductor layer of the LED and the second surface of the carrier substrate, respectively, constitute the positive terminal of the LED assembly, thereby connecting the LED and the circuit element integrated into the carrier substrate in an anti-parallel configuration. When a reverse bias voltage is applied across the positive and negative terminals of the LED assembly as described in the alternative embodiment, the circuit element will turn on and bypass the current from the LED, preventing the LED from being destroyed.

1. A light emitting diode (LED) assembly comprising:
a substrate comprising a region forming a circuit element;
an intervening layer formed on a surface of the substrate; and
an LED formed on the intervening layer,
wherein the intervening layer forms an ohmic connection between the region and the LED.

2. The LED assembly according to claim 1 wherein the intervening layer comprises a bonding layer bonding the LED to the substrate.

3. The LED assembly according to claim 1 wherein the LED and the substrate are connected to a first polarity of a voltage source, and the intervening layer is connected to a second polarity of the voltage source.

4. The LED assembly according to claim 1 further comprising:
a first electrode electrically coupled to the LED;
a second electrode electrically coupled to the intervening layer; and
a third electrode electrically coupled to the substrate.

5. The LED assembly according to claim 4 wherein the first electrode and the third electrode are connected to a first polarity of a voltage source, and the second electrode is connected to a second polarity of the voltage source.

6. The LED assembly according to claim 1 further comprising:
a passivation layer formed between the intervening layer and the substrate; and
an interconnect formed in the passivation layer,
wherein the interconnect forms an ohmic connection between the intervening layer and the region.

7. The LED assembly according to claim 1 wherein the circuit element forms an electro-static discharge (“ESD”) protection device.

8. The LED assembly according to claim 7 wherein the ESD protection device comprises a P-N junction.

9. The LED assembly according to claim 7 wherein the ESD protection device comprises a diode.

10. The LED assembly according to claim 7 wherein the ESD protection device comprises a Zener diode.

11. A method of forming an LED assembly, the method comprising:
providing a substrate comprising a region forming a circuit element;
forming an intervening layer on a surface of the substrate; and
forming an LED on the intervening layer,
wherein the intervening layer forms an ohmic connection between the region and the LED.

12. The method according to claim 11 wherein the intervening layer comprises a bonding layer bonding the LED to the substrate.

13. The method according to claim 11 further comprising:
connecting the LED and the substrate to a first polarity of a voltage source; and
connecting the intervening layer to a second polarity of the voltage source.

14. The method according to claim 11, further comprising:
forming a first electrode electrically coupled to the LED;
forming a second electrode electrically coupled to the intervening layer; and
forming a third electrode electrically coupled to the substrate.

15. The method according to claim 11 further comprising:
connecting the LED and the substrate to a first polarity of a voltage source; and
connecting the intervening layer to a second polarity of the voltage source.

16. The method according to claim 11, further comprising:
forming a passivation layer between the intervening layer and the substrate; and
forming an interconnect in the passivation layer,
wherein the interconnect forms an ohmic connection between the intervening layer and the region.

17. The method according to claim 11 wherein the circuit element forms an ESD protection device.

18. The method according to claim 17 wherein the ESD protection device comprises a P-N junction.

19. The method according to claim 17 wherein the ESD protection device comprises a diode.

20. The method according to claim 17 wherein the ESD protection device comprises a Zener diode.
